(19) United States
(12) Patent Application Publication
(10) Pub. No.: US 2022/0276540 A1
(43) Pub. Date: Sep. 1, 2022

(54) ARRAY SUBSTRATE, MANUFACTURING METHOD THEREOF AND DISPLAY PANEL

(71) Applicant: BOE Technology Group Co., Ltd., Beijing (CN)

(72) Inventors: Lizhong WANG, Beijing (CN); Ce NING, Beijing (CN); Binbin TONG, Beijing (CN); Zhen ZHANG, Beijing (CN); Fuqiang LI, Beijing (CN); Zhenyu ZHANG, Beijing (CN)

(21) Appl. No.: 17/504,402

(22) Filed: Oct. 18, 2021

(30) Foreign Application Priority Data
Feb. 26, 2021 (CN) 202110218665.X

(51) Int. Cl. G02F 1/1362; G02F 1/1368; H01L 27/12; H01L 29/786; H01L 21/02; H01L 29/66

(52) U.S. Cl. CPC G02F 1/136227; G02F 1/13685; G02F 1/136286; H01L 27/1225; H01L 27/1244; H01L 29/7869; H01L 27/127; H01L 21/02565; H01L 29/66969

(57) ABSTRACT

The disclosure provides an array substrate, a manufacturing method thereof and a display panel, and relates to the technical field of display. The array substrate comprises a first transistor arranged on one side of a substrate base, the first transistor being located in an active area of the array substrate; a flat layer covering the first transistor, the flat layer having a first through-hole; a first electrode layer arranged in the first through-hole, and being connected with a drain of the first transistor and having a first groove; a filling layer arranged in the first groove; and a second electrode layer arranged on a side, away from the first transistor, of the filling layer, the second electrode layer being connected with the first electrode layer. So an electric field for driving a liquid crystal layer is more uniform, thereby improving an aperture ratio of the display panel.

### CROSS REFERENCE TO RELEVANT DISCLOSURES

The present application claims the priority of the Chinese patent application filed on Feb. 26, 2021 before the Chinese Patent Office with the application number of 202110218665.X and the title of “ARRAY SUBSTRATE, MANUFACTURING METHOD THEREOF AND DISPLAY PANEL”, which is incorporated herein in its entirety by reference.

### TECHNICAL FIELD

The disclosure relates to the technical field of display, in particular to an array substrate, a manufacturing method thereof, and a display panel.

### BACKGROUND

In a display panel, in order to drive liquid crystal molecules, a through-hole needs to be formed in a flat layer covering a transistor, and a pixel electrode is connected with a drain of the transistor through the through-hole.

At present, when the through hole is formed in the flat layer to connect the pixel electrode with the drain of the transistor, light leakage will occur in a display panel. In order to solve the problem of light leakage of the display panel, a black matrix is arranged on a color film substrate or array substrate side.

However, by adoption of this method, the black matrix will block the light passing through an array substrate, which will reduce an aperture ratio of the display panel and further affect the display effect of the display panel.

### SUMMARY

The disclosure provides an array substrate, a manufacturing method thereof and a display panel.

The disclosure discloses an array substrate, comprising:

a substrate base;

a first transistor arranged on one side of the substrate base, the first transistor being located in an active area of the array substrate;

a flat layer covering the first transistor, the flat layer having a first through-hole;

a first electrode layer arranged in the first through-hole, the first electrode layer being connected with a drain of the first transistor and having a first groove;

a filling layer arranged in the first groove; and

a second electrode layer arranged on a side, away from the first transistor, of the filling layer, the second electrode layer being connected with the first electrode layer.

Optionally, a surface of a side, away from the first transistor, of the filling layer and a surface of a side, away from the first transistor, of the flat layer are on a same plane.

Optionally, the first transistor comprises a first active layer, a first gate insulating layer, a first gate, a first interlayer dielectric layer and a first source which are sequentially arranged on one side of the substrate base; and

the first source is connected with the first active layer through a first via hole penetrating through the first interlayer dielectric layer and the first gate insulating layer.

Optionally, the first transistor further comprises a first passivation layer covering the first source and the first interlayer dielectric layer, and a first drain arranged on the first passivation layer; and

the first drain is connected with the first active layer through a second via hole penetrating through the first passivation layer, the first interlayer dielectric layer and the first gate insulating layer.

Optionally, a second through-hole penetrates the first interlayer dielectric layer and the first gate insulating layer through-hole, and the second through-hole communicates with the first through-hole;

the first transistor further comprises a first drain arranged in the second through-hole, and the first drain is connected with the first active layer and has a second groove; and

the filling layer extends into the second groove.

Optionally, the first transistor comprises a second gate, a second interlayer dielectric layer, a second active layer, a second source and a second passivation layer which are sequentially arranged on one side of the substrate base; and

the second source partially covers the second active layer.

Optionally, the first transistor further comprises a second drain arranged on the second passivation layer; and

the second drain is connected with the second active layer through a third via hole penetrating through the second passivation layer.

Optionally, the second passivation layer has a third through-hole, and the third through-hole communicates with the first through-hole;

the first transistor further comprises a second drain arranged in the third through-hole, and the second drain is connected with the second active layer and has a third groove; and

the filling layer extends into the third groove.

Optionally, the array substrate further comprising a second transistor located in a GOA area, wherein the second transistor comprises a third active layer, a second gate insulating layer, a third gate, an insulating medium layer and a third source-drain electrode which are sequentially arranged on one side of the substrate base; and

a third source of the third source-drain electrode is connected with the third active layer through a fourth via hole penetrating through the insulating dielectric layer and the second gate insulating layer, a third drain of the third source-drain electrode is connected with the third active layer through a fifth via hole penetrating through the insulating dielectric layer and the second gate insulating layer, and the insulating dielectric layer comprises a third interlayer dielectric layer and a first gate insulating layer, or the insulating dielectric layer comprises a second interlayer dielectric layer.

Optionally, the first electrode layer and a drain of the first transistor are made of the same material, and both are a transparent conductive material; and

a material of an active layer of the first transistor is an oxide semiconductor.

The disclosure also discloses a display panel comprising the aforementioned array substrate.

The disclosure also discloses a manufacturing method of an array substrate, comprising:

forming a first transistor on one side of a substrate base, the first transistor being located in an active area of the array substrate;

forming a flat layer covering the first transistor, the flat layer having a first through-hole;

forming a first electrode layer in the first through-hole, the first electrode layer being connected with a drain of the first transistor and having a first groove;

forming a filling layer in the first groove; and

forming a second electrode layer on a side, away from the first transistor, of the filling layer, the second electrode layer being connected with the first electrode layer.

Optionally, a drain of the first transistor and the first electrode layer are simultaneously formed by a same patterning process.

### BRIEF DESCRIPTION OF THE DRAWINGS

FIG. 1 is a cross-sectional view of a first array substrate according to an embodiment of the disclosure;

FIG. 2 is a cross-sectional view of a second array substrate according to an embodiment of the disclosure;

FIG. 3 is a cross-sectional view of a third array substrate according to an embodiment of the disclosure;

FIG. 4 is a cross-sectional view of a fourth array substrate according to an embodiment of the disclosure; and

FIG. 5 is a flowchart of a manufacturing method of an array substrate according to an embodiment of the disclosure.

### DETAILED DESCRIPTION

In order to make the above objects, features and advantages of the disclosure better understood, the disclosure will be described in further detail below with reference to the accompanying drawings and detailed description.

In the related art, in order to drive liquid crystal molecules in a display panel, a through-hole is formed in a flat layer covering a transistor, and a pixel electrode is located in the through-hole and connected with a drain of the transistor. The pixel electrode is generally made of ITO (Indium Tin Oxides). Due to the limitation of the film forming process, an ITO film layer is too thin to fill the through-hole completely, resulting in a groove in the pixel electrode formed at the position of the through-hole, so that a different distance between the pixel electrode and a common electrode at different positions, and therefore an electric field for driving the liquid crystal molecules is nonuniform, causing light leakage of the display panel at a position corresponding to the through-hole. In order to solve the problem of light leakage, a black matrix is arranged at the position corresponding to the through-hole on an array substrate side or color film substrate side to shield the leaked light, but the arrangement of the black matrix will reduce an aperture ratio of the display panel.

In view of the above problem, in the embodiment of the disclosure, by arranging a filling layer in a first groove of a first electrode layer to fill the first groove, a segment gap between a second electrode layer located in the first groove and the second electrode layer located on the flat layer is reduced, making the second electrode layer flatter; therefore, an electric field provided by the second electrode layer for driving a liquid crystal layer is more uniform, which weakens the light leakage phenomenon of the display panel; in addition, a black matrix is not needed, thereby improving an aperture ratio of the display panel.

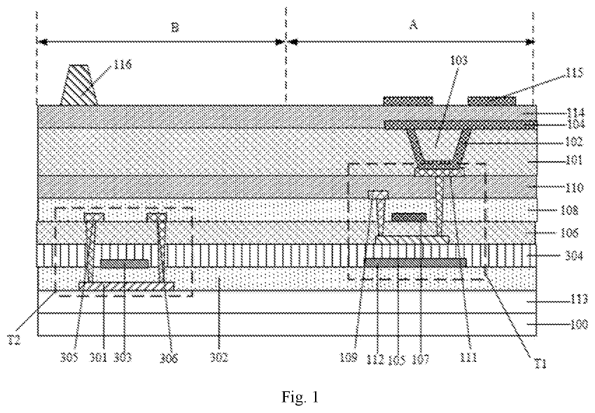

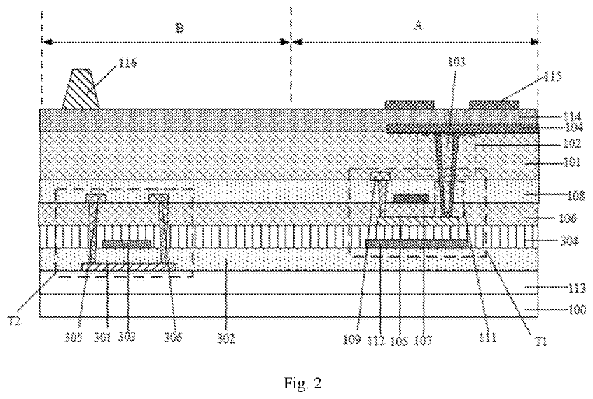

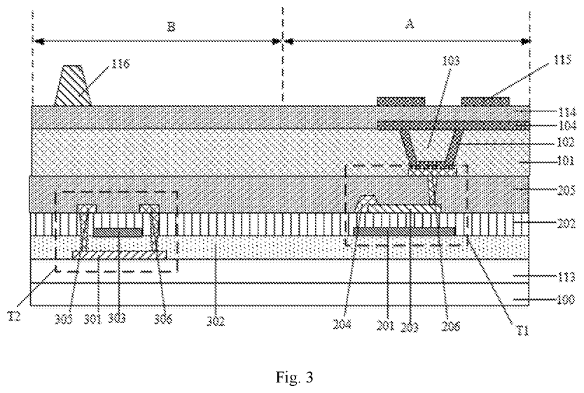

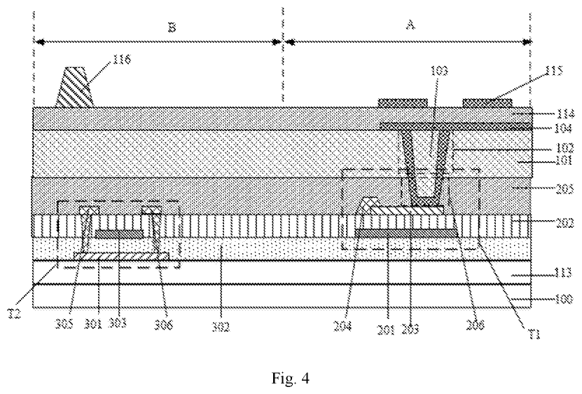

FIG. 1 is a cross-sectional view of a first array substrate according to an embodiment of the disclosure; FIG. 2 is a cross-sectional view of a second array substrate according to an embodiment of the disclosure; FIG. 3 is a cross-sectional view of a third array substrate according to an embodiment of the disclosure; and FIG. 4 is a cross-sectional view of a fourth array substrate according to an embodiment of the disclosure.

The embodiment of the disclosure provides an array substrate, which comprises a substrate base 100; a first transistor T1 arranged on one side of the substrate base 100, the first transistor T1 being located in an active area A of the array substrate; a flat layer 101 covering the first transistor T1, the flat layer 101 having a first through-hole; a first electrode layer 102 arranged in the first through-hole, the first electrode layer 102 being connected with a drain of the first transistor T1 and having a first groove; a filling layer 103 arranged in the first groove; and a second electrode layer 104 arranged on a side, away from the first transistor T1, of the filling layer 103, the second electrode layer 104 being connected with the first electrode layer 102.

In the embodiment of the disclosure, the array substrate comprises the flat layer 101 covering the first transistor T1 located in the active area, the flat layer 101 extends to a GOA (Gate Driver On Array) area B of the array substrate, and the flat layer 101 has a first through-hole which is arranged in a direction perpendicular to the substrate base 100. The first electrode layer 102 is arranged in the first through-hole. Because the first electrode layer 102 is thin, the first electrode layer 102 is only distributed on a sidewall and bottom of the first through-hole, and the first through-hole will not be completely filled, so that the formed first electrode layer 102 has the first groove. The filling layer 103 is arranged in the first groove, the second electrode layer 104 is arranged on the side, away from the first transistor T1, of the filling layer 103, the second electrode layer 104 extends to a surface of a side, away from the first transistor T1, of the flat layer 101, and the first electrode layer 102 is connected with the second electrode layer 104.

The drain of the first transistor T1 is connected with the second electrode layer 104 through the first electrode layer 102, so that the first transistor T1 may control the rotation of liquid crystal molecules in the display panel through the second electrode layer 104. The first transistor T1 is used to control the rotation of liquid crystal molecules in each pixel unit.

Along the direction perpendicular to the substrate base 100, a thickness of the flat layer 101 is 0.5-3 μm, and an aperture of the first through-hole is 2-5 μm. In actual products, an orthographic projection of the first through-hole on the substrate base is a closed shape, such as a circle or a rectangle. When the orthographic projection of the first through-hole on the substrate base is a circle, the aperture refers to a diameter of the circle; and when the orthographic projection of the first through-hole on the substrate base is a rectangle, the aperture refers to a side length of each side of the rectangle.

The first electrode layer 102 has the first groove, and a thickness of the first electrode layer 102 in a direction perpendicular to a sidewall of the first groove is 30-100 nm. A thickness of the second electrode layer 104 is 30-100 nm in the direction perpendicular to the substrate base 100. Both the first electrode layer 102 and the second electrode layer 104 are made of transparent conductive materials, such as ITO. The filling layer 103 and the flat layer 101 are both made of organic materials, and the material of the filling layer 103 may be the same as or different from that of the flat layer 101.

In the embodiment of the disclosure, since the filling layer 103 is arranged in the first groove, a depth of the first groove in the direction perpendicular to the substrate base 100 is reduced. After the second electrode layer 104 is formed, a segment gap between the second electrode layer 104 located in the first groove and the second electrode layer 104 located on the flat layer 101 is reduced, so that an electric field for driving a liquid crystal layer subsequently is more uniform, and the light leakage phenomenon of the display panel is weakened; in addition, a black matrix is not needed, thereby improving an aperture ratio of the display panel.

In the embodiment of the disclosure, a surface of a side, away from the first transistor T1, of the filling layer 103 and a surface of a side, away from the first transistor T1, of the flat layer 101 are on a same plane.

In the embodiment of the disclosure, the filling layer 103 is arranged in the first groove in the first electrode layer 102, and a thickness of the filling layer 103 may be set according to actual conditions. Optionally, when the first groove is filled with the filling layer 103, the surface of the side, away from the first transistor T1, of the filling layer 103 and the surface of the side, away from the first transistor T1, of the flat layer 101 are on the same plane. Therefore, after the second electrode layer 104 is formed, the segment gap between the second electrode layer 104 located in the first groove and the second electrode layer 104 located on the flat layer 101 is zero, that is, the second electrode layer 104 located in the first groove and the second electrode layer 104 located on the flat layer 101 are on the same plane, which makes the second electrode layer 104 flatter. Therefore, the electric field provided by the second electrode layer 104 for driving the liquid crystal layer is more uniform, thus avoiding light leakage of the display panel.

In the embodiment of the disclosure, as shown in FIGS. 1 and 2, the first transistor T1 comprises a first active layer 105, a first gate insulating layer 106, a first gate 107, a first interlayer dielectric layer 108 and a first source 109 which are sequentially arranged on one side of the substrate base 100, wherein the first source 109 is connected with the first active layer 105 through a first via hole penetrating through the first interlayer dielectric layer 108 and the first gate insulating layer 106.

When the first transistor T1 is a top gate transistor, the first transistor T1 comprises the first active layer 105 arranged on one side of the substrate base 100, and the first gate insulating layer 106 covering the first active layer 105 and extending to the GOA area; besides, the first gate 107 is arranged on the first gate insulating layer 106, the first interlayer dielectric layer 108 covers the first gate 107 and the first gate insulating layer 106, the first source 109 is arranged on a side, away from the first gate 107, of the first interlayer dielectric layer 108, and the first source 109 is connected with the first active layer 105 through the first via hole penetrating through the first interlayer dielectric layer 108 and the first gate insulating layer 106, wherein the first interlayer dielectric layer 108 also extends to the GOA area.

In an optional embodiment of the disclosure, as shown in FIG. 1, the first transistor T1 further comprises a first passivation layer 110 covering the first source 109 and the first interlayer dielectric layer 108, and a first drain 111 arranged on the first passivation layer 110, wherein the first drain 111 is connected with the first active layer 105 through a second via hole penetrating through the first passivation layer 110, the first interlayer dielectric layer 108 and the first gate insulating layer 106.

In the embodiment of the disclosure, the first transistor T1 further comprises the first passivation layer 110 covering the first source 109 and the first interlayer dielectric layer 108, and the first drain 111 is arranged on a side, away from the first source 109, of the first passivation layer 110. The first passivation layer 110, the first interlayer dielectric layer 108 and the first gate insulating layer 106 have a second via hole, and the first drain 111 is connected with the first active layer 105 through the second via hole. The first drain 111 arranged on the side, away from the first source 109, of the first passivation layer 110 is also connected with the first electrode layer 102 located in the first via hole, wherein the first passivation layer 110 also extends to the GOA area B and covers the first interlayer dielectric layer 108 located in the GOA area.

The first source 109 is located on the side, away from the first gate 107, of the first interlayer dielectric layer 108, the first drain 111 is located on the side, away from the first source 109, of the first passivation layer 110, and the first drain 111 and the first source 109 are arranged on different layers. In this case, the first passivation layer 110 is arranged between the first source 109 and the first drain 111. When the first drain 111 and the first source 109 are arranged on different layers, the first source 109 and the first drain 111 may be arranged closer in a direction parallel to the substrate base 100, that is, a size of the first transistor T1 may be reduced, so that more first transistors T1 may be arranged on the substrate base 100, thereby improving the resolution of the display panel. In addition, since the first source 109 and the first drain 111 are arranged on different layers, the short-circuit problem between the first source 109 and the first drain 111 may also be avoided.

When the first transistor T1 is a top gate transistor, a drain of the first transistor T1 is the first drain 111 with a thickness of 50-600 nm, a source in the first transistor T1 is the first source 109, and a gate in the first transistor T1 is the first gate 107 with a thickness of 300-700 nm.

A material of the first gate 107 is a metal, such as Ti/Al/Ti and Mo. A material of the first drain 111 may be a conventional metal, such as Cu, Mo, Ti/Al/Ti, or a transparent metal, such as ITO.

A material of the first passivation layer 110 is at least one of silicon oxide and silicon nitride, that is, the first passivation layer 110 may be a single layer of silicon oxide or silicon nitride or a laminated structure of silicon oxide and silicon nitride, and a thickness of the first passivation layer 110 is 50-300 nm.

In another optional embodiment of the disclosure, as shown in FIG. 2, the first interlayer dielectric layer 108 and the first gate insulating layer 106 have a second through-hole, and the second through-hole communicates with the first through-hole. The first transistor T1 further comprises a first drain 111 arranged in the second through-hole, and the first transistor T1 is connected with the first active layer 105 and has a second groove. The filling layer 103 extends into the second groove, and the first drain 111 in the second through-hole is connected with the first electrode layer 102 in the first through-hole.

In the embodiment of the disclosure, a second through-hole penetrates the first interlayer dielectric layer 108 and the first gate insulating layer 106 through-hole, and the first through-hole penetrating through the flat layer 101 communicates with the second through-hole, that is, an overlapping area exists between an orthographic projection of the first through-hole on the substrate base 100 and an orthographic projection of the second through-hole on the substrate base 100.

The first through-hole and the second through-hole may be formed only by one photomask. The flat layer 101 is exposed and developed by one photomask to form the first through-hole, and then the first interlayer dielectric layer 108 and the first gate insulating layer 106 are etched by using the flat layer 101 as a photomask to form the second through-hole. In this way, one photomask may be saved, and the process is simplified.

In this case, a drain of the first transistor T1 is the first drain 111, the first drain 111 is located in the second through-hole and connected with the first active layer 105, and the first drain 111 and the first electrode layer 102 are simultaneously formed by a one-step patterning process, thus simplifying the process of forming the first transistor T1.

The first drain 111 has a second groove, and the filling layer 103 in the first groove extends into the second groove. An overlapping area should exist between an orthographic projection of the filling layer 103 in the second groove on the substrate base 100 and an orthographic projection of the filling layer 103 in the first groove on the substrate base 100. The first drain 111 is arranged in the second through-hole. Since a film layer of the first drain 111 is thin, the first drain 111 will only be distributed on a sidewall and bottom of the second through-hole, and the second through-hole will not be filled completely, so that the formed first drain 111 has the second groove and an overlapping area exists between an orthographic projection of the second groove on the substrate base 100 and an orthographic projection of the first groove on the substrate base 100.

In the embodiment of the disclosure, as shown in FIGS. 3 and 4, the first transistor T1 comprises a second gate 201, a second interlayer dielectric layer 202, a second active layer 203, a second source 204 and a second passivation layer 205 which are sequentially arranged on one side of the substrate base 100. The second source 204 partially covers the second active layer 203.

When the first transistor T1 is a bottom gate transistor, the first transistor T1 comprises the second gate 201 arranged on one side of the substrate base, the second interlayer dielectric layer 202 covering the second gate 201, and the second active layer 203 located on a side, away from the second gate 201, of the second interlayer dielectric layer 202. The first transistor T1 also comprises the second source 204, wherein part of the second source 204 covers the second active layer 203 and the other part covers the second interlayer dielectric layer 202. The first transistor T1 also comprises the second passivation layer 205 covering the second source 204, the second active layer 203 and the second interlayer dielectric layer 202, and the second passivation layer 205 extends to the GOA area B.

A thickness of the second passivation layer 205 is 50-300 nm, and a material of the second passivation layer 205 is at least one of silicon oxide and silicon nitride, that is, the second passivation layer 205 may be a single layer of silicon oxide or silicon nitride, or a laminated structure of silicon oxide and silicon nitride.

In an optional embodiment of the disclosure, as shown in FIG. 3, the first transistor T1 further comprises a second drain 206 arranged on the second passivation layer 205, and the second drain 206 is connected with the second active layer 203 through a third via hole penetrating through the second passivation layer 205.

In the embodiment of the disclosure, the first transistor T1 further comprises the second drain 206 arranged on a side, away from the second active layer 203, of the second passivation layer 205, the second passivation layer 205 has the third via hole, and the second drain 206 is connected with the second active layer 203 through the third via hole. The second drain 206 is connected with the first electrode layer 102, and the first electrode layer 102 is also connected with the second electrode layer 104. Therefore, the first transistor T1 may control the rotation of liquid crystal molecules in the display panel through the first electrode layer 102 and the second electrode layer 104, and the second drain 206 arranged on the side, away from the second source 204, of the second passivation layer 205 is also connected with the first electrode layer 102 located in the first through-hole.

When the first transistor T1 is a bottom gate transistor, a drain of the first transistor T1 is the second drain 206 with a thickness of 50-600 nm, a source of the first transistor T1 is the second source 204, and a gate in the first transistor T1 is the second gate 201 with a thickness of 300-700 nm.

A material of the second gate 201 is a metal, such as Ti/Al/Ti and Mo. A material of the second drain 206 may be a conventional metal, such as Cu, Mo, Ti/Al/Ti, or a transparent metal, such as ITO.

In another optional embodiment of the disclosure, as shown in FIG. 4, the second passivation layer 205 has a third through-hole which communicates with the first through-hole. The first transistor T1 also comprises a second drain 206 arranged in the third through-hole, and the second drain 206 is connected with the second active layer 203 and has a third groove. The filling layer 103 extends into the third groove.

In the embodiment of the disclosure, the second passivation layer 205 has the third through-hole which communicates with the first through-hole penetrating through the flat layer 101, that is, an overlapping area exists between the orthographic projection of the first through-hole on the substrate base 100 and an orthographic projection of the third through-hole on the substrate base 100.

The first through-hole and the third through-hole may be formed only by one photomask. The flat layer 101 is exposed and developed by one photomask to form the first through-hole, and then the second passivation layer 205 is etched by using the flat layer 101 as a photomask to form the third through-hole. In this way, one photomask may be saved, and the process is simplified.

The first transistor T1 also comprises the second drain 206, and the second drain 206 is located in the third through-hole and connected with the second active layer 203. The second drain 206 and the first electrode layer 102 are simultaneously formed by the same patterning process, thus simplifying the process of forming the first transistor T1. Of course, the second drain 206 and the first electrode layer 102 may also be formed separately, which is not limited by the embodiment of the disclosure. The second drain 206 located in the third through-hole is connected with the first electrode layer 102 located in the first through-hole.

The second drain 206 is located in the third through-hole. Because a film layer of the second drain 206 is thin, the second drain 206 will only be distributed on a sidewall and bottom of the third through-hole, and the third through-hole will not be completely filled, so that the formed third drain 206 has a third groove, and an overlapping area exists between an orthographic projection of the third groove on the substrate base 100 and the orthographic projection of the first groove on the substrate base 100. The filling layer 103 in the first groove extends into the third groove, and an overlapping area should exist between an orthographic projection of the filling layer 103 in the third groove on the substrate base 100 and an orthographic projection of the filling layer 103 in the first groove on the substrate base 100.

In the embodiment of the disclosure, the array substrate further comprises a second transistor T2 located in the GOA area B, and the second transistor T2 comprises a third active layer 301, a second gate insulating layer 302, a third gate 303, an insulating dielectric layer and a third source-drain electrode which are sequentially arranged on one side of the substrate base. A third source 305 in the third source-drain electrode is connected with the third active layer 301 through a fourth via hole penetrating through the insulating dielectric layer and the second gate insulating layer 302, and a third drain 306 in the third source-drain electrode is connected with the third active layer 301 through a fifth via hole penetrating through the insulating dielectric layer and the second gate insulating layer 302. The insulating dielectric layer comprises a third interlayer dielectric layer 304 and the first gate insulating layer 106, or the insulating dielectric layer comprises the second interlayer dielectric layer 202.

In the embodiment of the disclosure, the array substrate further comprises the second transistor T2 located in the GOA area B, the second transistor T2 comprising the third active layer 301 arranged on a side, facing a light-exiting surface of the array substrate, of the substrate base 100; the second gate insulating layer 302 covering the third active layer 301 and extending to the active area A; the third gate 303 located on a side, away from the third active layer 301, of the second gate insulating layer 302; the insulating dielectric layer covering the third gate 303; and the third source-drain electrode located on a side, away from the third gate 303, of the insulating dielectric layer. The insulating dielectric layer and the second gate insulating layer 302 have the fourth via hole and the fifth via hole. The third source 305 in the third source-drain electrode is connected with the third active layer 301 through the fourth via hole penetrating through the insulating dielectric layer and the second gate insulating layer 302, and the third drain 306 in the third source-drain electrode is connected with the third active layer 301 through the fifth via hole penetrating through the insulating dielectric layer and the second gate insulating layer 302.

When the second transistor T2 and the top gate first transistor T1 are simultaneously formed on the substrate base 100, as shown in FIGS. 1 and 2, the insulating dielectric layer comprises the third interlayer dielectric layer 304 and the first gate insulating layer 106, and the third gate 303 in the second transistor T2 and a light shielding layer 112 in the first transistor T1 are simultaneously formed by a one-step patterning process. In this case, the third gate 303 and the light shielding layer 112 are arranged on a same layer, and the third source-drain electrode in the second transistor T2 and the first gate 107 in the first transistor T1 are also simultaneously formed by a one-step patterning process. In this case, the third source-drain electrode and the first gate 107 are arranged on a same layer, thus simplifying the manufacturing process.

When the second transistor T2 and the bottom gate first transistor T1 are simultaneously formed on the substrate base 100, as shown in FIGS. 3 and 4, the insulating dielectric layer comprises the second interlayer dielectric layer 202, the second interlayer dielectric layer 202 extends to the active area A, and the third gate 303 in the second transistor T2 and the second gate 201 in the first transistor T1 are simultaneously formed by a one-step patterning process. In this case, the third gate 303 and the second gate 201 are arranged on a same layer, and the third source-drain electrode in the second transistor T2 and the second source 204 in the first transistor T1 are simultaneously formed by a one-step patterning process. In this case, the third source-drain electrode and the second transistor T2 are arranged on a same layer, thus solving the problem of low process integration when the first transistor T1 and the second transistor T2 are formed separately. By arranging the third gate 303 and the second gate 201 on the same layer and arranging the third source-drain electrode and the second source 204 on the same layer, a film layer structure of the array substrate is simplified and the manufacturing process is simplified.

In a traditional array substrate, transistors in the active area and transistors in the GOA area are made separately, so process integration is low, the array substrate has many layers and is thick, and the manufacturing process is complicated. In the embodiment of the disclosure, the first transistor T1 and the second transistor T2 are arranged in the above manner, which improves process integration and reduces the number of film layers of the array substrate, thus reducing the thickness of the array substrate and simplifying the manufacturing process.

The second transistor T2 is a transistor in a GOA circuit, and used to provide a gate driving signal for the first transistor T1.

A thickness of the third gate 303 is 50-500 nm, and thicknesses of the third source 305 and the third drain 306 are 300-700 nm. The third gate 303, the third source 305 and the third drain 306 are all made of metals. Specifically, the third gate 303, the third source 305 and the third drain 306 may be of a single layer structure, which is made of metal, such as Mo; and the third gate 303, the third source 305 and the third drain 306 may also be of a laminated structure, and each layer is made of metal, for example, a Ti/Al/Ti laminated structure.

Optionally, in the embodiment of the disclosure, the array substrate further comprises a buffer layer 113 covering the substrate base 100, wherein the buffer layer 113 in the GOA area B is arranged between the substrate base 100 and the third active layer 301, the buffer layer 113 in the active area A is located between the second gate insulating layer 302 and the substrate base 100, and the buffer layer 113 is arranged to prevent impurities in the substrate base 100 from entering the first transistor T1 and the second transistor T2, which may otherwise affect the performance of the first transistor T1 and the second transistor T2.

In addition, as shown in FIGS. 1 and 2, the first transistor T1 further comprises the light shielding layer 112 and the second gate insulating layer 302, wherein the second gate insulating layer 302 is located on a side, away from the substrate base 100, of the buffer layer 113, and the light shielding layer 112 is located between the second gate insulating layer 302 and the third interlayer dielectric layer 304. Of course, the light shielding layer 112 may also be arranged between the substrate base 100 and the buffer layer 113, and a specific position of the light shielding layer 112 may be determined according to the actual situation, which is not limited by the embodiment of the disclosure.

The light shielding layer 112 is arranged to prevent backlight from being incident on the first active layer 105, which may otherwise affect the stability of the first transistor T1. In this embodiment, the light shielding layer 112 prevents the influence of the backlight on the first active layer 105 of the first transistor T1, thus ensuring the stability of the first transistor T1.

In the embodiment of the disclosure, a material of the first electrode layer 102 and a material of the drain of the first transistor T1 are the same, and both are transparent conductive materials. A material of the active layer of the first transistor T1 is an oxide semiconductor.

In the embodiment of the disclosure, a material of the first electrode layer 102 is the same as that of the drain of the first transistor T1, and materials of the first electrode layer 102 and the drain of the first transistor T1 are transparent conductive materials, such as ITO. When the drain of the first transistor T1 is made of transparent conductive materials, the light transmittance of the display panel may be increased and the display effect of the display panel may be improved. In addition, when the material of the first electrode layer 102 is the same as that of the drain of the first transistor T1, the first electrode layer 102 and the drain of the first transistor T1 may be simultaneously formed by a one-step patterning process, so as to simplify the manufacturing process.

Of course, the drain of the first transistor T1 may also be made of a different material from the first electrode layer 102. The drain of the first transistor T1 is made of conductive materials such as Cu, Mo, Ti/Al/Ti, and the first electrode layer 102 is made of conductive materials such as ITO.

The active layer of the first transistor T1 is made of an oxide semiconductor, which is the first active layer 105 when the first transistor T1 is a top gate transistor, and the second active layer 203 when the first transistor T1 is a bottom gate transistor, i.e., the first active layer 105 and the second active layer 203 are made of oxide semiconductor materials, for example, IGZO (indium gallium zinc oxide).

The traditional first transistor T1 located in the active area uses low-temperature polysilicon materials to make the active layer. When low-temperature polysilicon materials are in contact with the drain of the first transistor T1 and the drain is made of transparent conductive materials, a contact surface is easily oxidized, thus increasing contact resistance and further affecting the performance of the first transistor T1. In the embodiment of the disclosure, the first active layer 105 or the second active layer 203 is made of an oxide semiconductor, and when the drain of the first transistor T1 is made of transparent conductive materials, a contact surface will not be oxidized when the first active layer 105 and the second active layer 203 make contact with the drain of the first transistor T1, which will not affect the contact resistance, thus ensuring the performance of the first transistor T1. The transparency of oxide semiconductor materials is greater than that of low-temperature polysilicon materials. Therefore, by making the source of the first transistor T1 of oxide semiconductor materials, the light transmittance of the display panel may be improved.

In the embodiment of the disclosure, as shown in FIGS. 1 to 4, the array substrate further comprises a third passivation layer 114 covering the second electrode layer 104 and the flat layer 101, and a third electrode layer 115 and a supporting structure 116 which are located on a side, away from the second electrode layer 104, of the third passivation layer 114. The third electrode layer 115 is located in the active area A, and an overlapping area exists between an orthographic projection of the third electrode layer 115 on the substrate base 100 and an orthographic projection of the second electrode layer 104 on the substrate base 100.

In the embodiment of the disclosure, the array substrate further comprises the third passivation layer 114, the supporting structure 116 and the third electrode layer 115, wherein the third passivation layer 114 covers the second electrode layer 104 and the flat layer 101, and the arrangement of the third passivation layer 114 may prevent water vapor from entering the flat layer 101, thus avoiding the influence of water vapor on the stability of the first transistor T1.

The supporting structure 116 is located on the side, away from the second electrode layer 104, of the third passivation layer 114, the supporting structure 116 is located in the GOA area B or the active area A, which is not limited by the embodiment of the disclosure, and the supporting structure 116 is arranged to support a color film substrate formed later.

The third electrode layer 115 is located on the side, away from the second electrode layer 104, of the third passivation layer 114, and is located in the active area A. The third electrode layer 115 and the supporting structure 116 are arranged on a same layer. An overlapping area exists between an orthographic projection of the third electrode layer 115 on the substrate base 100 and an orthographic projection of the second electrode layer 104 on the substrate base 100. The third electrode layer 115 is a common electrode layer, the second electrode layer 104 and the first electrode layer 102 together constitute a pixel electrode layer, and the third electrode layer 115 and the pixel electrode layer together drive a liquid crystal layer in the display panel.

A thickness of the third electrode layer 115 is 30-100 nm, and the thicknesses of the third electrode layer 115, the second electrode layer 104 and the first electrode layer 102 may be the same or different. A thickness of the third passivation layer 114 is 50-300 nm.

A material of the third electrode layer 115 is a transparent conductive material, such as ITO, and a material of the third passivation layer 114 is at least one of silicon oxide and silicon nitride, that is, the third passivation layer 114 may be a single layer of silicon oxide or silicon nitride or a laminated structure of silicon oxide and silicon nitride. The materials of the first passivation layer 110, the second passivation layer 205, and the third passivation layer 114 may be the same or different.

In the embodiment of the disclosure, by arranging the filling layer in the first groove of the first electrode layer to fill the first groove, a segment gap between the second electrode layer located in the first groove and the second electrode layer located on the flat layer is reduced, making the second electrode layer flatter; therefore, an electric field provided by the second electrode layer for driving a liquid crystal layer is more uniform, which weakens the light leakage phenomenon of the display panel; in addition, a black matrix is not needed, thereby improving an aperture ratio of the display panel.

The embodiment of the disclosure also provides a display panel, which comprises the array substrate.

The display panel may be an LCD (Liquid Crystal Display) or OLED (Organic Light-Emitting Diode) display panel. When the display panel is an LCD display panel, the display panel also comprises a color film substrate opposite to the array substrate, a liquid crystal layer between the array substrate and the color film substrate, a first polarizer on a side, away from the array substrate, of the color film substrate, and a second polarizer on a side, away from the color film substrate, of the array substrate.

In practical application, the display panel may be applied to any products or components with a display function, such as mobile phone, tablet personal computer, television, display, notebook computer and navigator.

In the embodiment of the disclosure, by arranging the filling layer in the first groove of the first electrode layer to fill the first groove, a segment gap between the second electrode layer located in the first groove and the second electrode layer located on the flat layer is reduced, making the second electrode layer flatter; therefore, an electric field provided by the second electrode layer for driving a liquid crystal layer is more uniform, which weakens the light leakage phenomenon of the display panel; in addition, a black matrix is not needed, thereby improving an aperture ratio of the display panel.

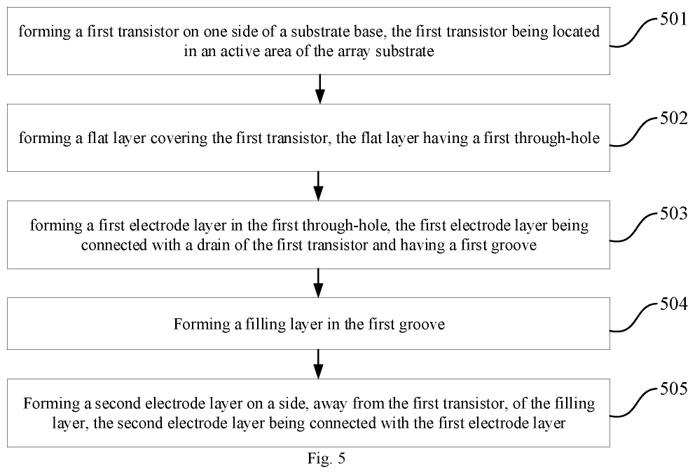

FIG. 5 is a flowchart of a manufacturing method of an array substrate according to an embodiment of the disclosure, which may specifically comprise the following steps:

Step 501, forming a first transistor on one side of a substrate base, the first transistor being located in an active area of the array substrate.

In the embodiment of the disclosure, the array substrate comprises an active area A and a GOA area B, a substrate base 100 is provided, and a first transistor T1 is formed on a side, located in the active area A, of the substrate base 100. The first transistor T1 may be a top gate transistor or a bottom gate transistor.

When the first transistor T1 is a top gate transistor, as shown in FIG. 1, the first transistor T1 is formed as follows: forming a first active layer 105 on one side of the substrate base 100; forming a first gate insulating layer 106 covering the first active layer 105; forming a first gate 107 on a side, away from the first active layer 105, of the first gate insulating layer 106; forming a first interlayer dielectric layer 108 covering the first gate 107 and the first gate insulating layer 106; forming a first via hole penetrating through the first interlayer dielectric layer 108 and the first gate insulating layer 106, and a first source 109 on a side, away from the first gate 107, of the first interlayer dielectric layer 108, and making the first source 109 connected with the first active layer 105 through the first via hole; and forming a first passivation layer 110 covering the first source 109 and the first interlayer dielectric layer 108, a second via hole penetrating through the first passivation layer 110, the first interlayer dielectric layer 108 and the first gate insulating layer 106, and a first drain 111 on a side, away from the first source 109, of the first passivation layer 110, and making the first drain 111 connected with the first active layer 105 through the second via hole.

When the first transistor T1 is a bottom gate transistor, as shown in FIG. 3, the first transistor T1 is formed as follows: forming a second gate 201 on one side of the substrate base 100; forming a second interlayer dielectric layer 202 covering the second gate 201; forming a second active layer 203 on a side, away from the second gate 201, of the second interlayer dielectric layer 202; forming a second source 204 with one part covering the second active layer 203 and the other part covering the second interlayer dielectric layer 202; forming a second passivation layer 205 covering the second source 204, the second active layer 203 and the second interlayer dielectric layer 202; forming a third via hole penetrating through the second passivation layer 205; and forming a second drain 206 on a side, away from the second active layer 203, of the second passivation layer 205, and making the second drain 206 connected with the second active layer 203 through the third via hole.

Step 502, forming a flat layer covering the first transistor, the flat layer having a first through-hole.

In the embodiment of the disclosure, after the first transistor T1 is formed, a flat layer film covering the first transistor T1 is formed, the flat layer film is exposed and developed to form a flat layer 101 with a first through-hole penetrating through the flat layer 101, and the first through-hole allows a first electrode layer 102 formed subsequently to make contact with a drain of the first transistor T1.

Step 503, forming a first electrode layer in the first through-hole, the first electrode layer being connected with a drain of the first transistor and having a first groove.

In the embodiment of the disclosure, after the first through-hole penetrating through the flat layer 101 is formed, the first electrode layer 102 is formed in the first through-hole, and the first electrode layer 102 is in contact with the drain of the first transistor T1, so that the first transistor T1 may transmit a signal for controlling the rotation of liquid crystal molecules to a second electrode layer 104 formed subsequently through the first electrode layer 102.

The first electrode layer 102 is made of a transparent conductive material, such as ITO. When ITO is used to make the first electrode layer 102, the first electrode layer 102 cannot be made very thick due to the limitation of the ITO film forming process, which is generally less than 1 μm. An aperture of the first through-hole is about 2-5 μm, and a depth of the first through-hole is about 1.5 μm. Therefore, the first electrode layer 102 cannot completely fill the first through-hole, resulting in a first groove in the first electrode layer 102.

Step 504, forming a filling layer in the first groove.

In the embodiment of the disclosure, the first electrode layer 102 has a first groove. After the first electrode layer 102 is formed, a filling layer film covering the flat layer 101 and the first electrode layer 102 is formed. The filling layer film in the first groove is retained by a patterning process, and the filling layer film in areas other than the first groove is removed to form a filling layer 103.

A thickness of the filling layer 103 may be set according to actual requirements. Preferably, the surface of the side, away from the first transistor T1, of the filling layer 103 and the surface of the side, away from the first transistor T1, of the flat layer 101 may be on the same plane. Therefore, after the second electrode layer 104 is formed later, the segment gap between the second electrode layer 104 located in the first groove and the second electrode layer 104 located on the flat layer 101 is zero, that is, the second electrode layer 104 located in the first groove and the second electrode layer 104 located on the flat layer 101 are on the same plane, which makes the second electrode layer 104 flatter. Therefore, the electric field provided by the second electrode layer 104 for driving the liquid crystal layer is more uniform, thus avoiding light leakage of the display panel.

Step 505, forming a second electrode layer on a side, away from the first transistor, of the filling layer, the second electrode layer being connected with the first electrode layer.

In the embodiment of the disclosure, after forming the filling layer 103, a second electrode layer 104 is formed on a side, away from the substrate base, of the filling layer 103, the second electrode layer 104 is connected with the first electrode layer 102, and the first electrode layer 102 is also connected with the drain of the first transistor T1, so that the first transistor T1 may be connected with the second electrode layer 104 through the first electrode layer 102, and the first transistor T1 may control the rotation of liquid crystal molecules in the display panel through the second electrode layer 104.

In the embodiment of the disclosure, the drain of the first transistor T1 and the first electrode layer 102 may be made of the same or different materials. When the drain of the first transistor T1 and the first electrode layer 102 are made of the same material, the drain of the first transistor T1 and the first electrode layer 102 are simultaneously formed by a same patterning process.

For a top gate first transistor T1, as shown in FIG. 2, after forming the first source 109, the flat layer 101 covering the first source 109 and the first interlayer dielectric layer 108 is directly formed, then a photomask is used to expose and develop the flat layer 101 to form the first through-hole penetrating through the flat layer 101, then the first interlayer dielectric layer 108 and the first gate insulating layer 106 are etched with the flat layer 101 as a photomask, so as to form the second through-hole penetrating through the first interlayer dielectric layer 108 and the first gate insulating layer 106, and the first through-hole communicates with the second through-hole; finally, the first drain 111 is formed in the second through-hole and the first electrode layer 102 is formed in the first through-hole by a one-step patterning process; and the first drain 111 is connected with the first electrode layer 102, that is, the first electrode layer 102 and the first drain 111 are simultaneously formed by a same patterning process.

For a bottom gate first transistor T1, as shown in FIG. 4, after forming the second passivation layer 205, the flat layer 101 covering the second passivation layer 205 is formed, then a photomask is used to expose and develop the flat layer 101 to form the first through-hole penetrating through the flat layer 101, then the second passivation layer 205 is etched with the flat layer as a photomask to form the third through-hole penetrating through the second passivation layer 205, and the first through-hole communicates with the third through-hole; finally, the second drain 206 is formed in the third through-hole and the first electrode layer 102 is formed in the first through-hole by a one-step patterning process; and the second drain 206 is connected with the first electrode layer 102, that is, the first electrode layer 102 and the second drain 206 are simultaneously formed by a same patterning process.

A conventional drain of the first transistor T1 needs to be formed by a single patterning process, and the first electrode layer 102 also needs to be formed by a single patterning process. However, in the embodiment of the disclosure, the first electrode layer 102 and the drain of the first transistor T1 are simultaneously formed by the same patterning process, which simplifies the manufacturing process.

In the embodiment of the disclosure, by arranging the filling layer in the first groove of the first electrode layer to fill the first groove, a segment gap between the second electrode layer located in the first groove and the second electrode layer located on the flat layer is reduced, making the second electrode layer flatter; therefore, an electric field provided by the second electrode layer for driving a liquid crystal layer is more uniform, which weakens the light leakage phenomenon of the display panel; in addition, a black matrix is not needed, thereby improving an aperture ratio of the display panel.

Compared with the related art, the disclosure has the following advantages:

In the embodiment of the disclosure, the array substrate comprises a substrate base; a first transistor arranged on one side of the substrate base, the first transistor being located in an active area of the array substrate; a flat layer covering the first transistor, the flat layer having a first through hole; a first electrode layer arranged in the first through hole, the first electrode layer being connected with a drain of the first transistor and having a first groove; a filling layer arranged in the first groove; and a second electrode layer arranged on a side, away from the first transistor, of the filling layer, the second electrode layer being connected with the first electrode layer. By arranging the filling layer in the first groove of the first electrode layer to fill the first groove, a segment gap between the second electrode layer located in the first groove and the second electrode layer located on the flat layer is reduced, making the second electrode layer flatter; therefore, an electric field provided by the second electrode layer for driving a liquid crystal layer is more uniform, which weakens the light leakage phenomenon of the display panel; in addition, a black matrix is not needed, thereby improving an aperture ratio of the display panel.

For the sake of simple description, all the aforementioned method embodiments are expressed as a series of action combinations, but those skilled in the art should know that the disclosure is not limited by the described action sequence, because according to the disclosure, some steps can be performed in other sequences or at the same time. Those skilled in the art should also know that the embodiments described in the specification are all preferred embodiments, and the actions and modules involved are not necessarily a must for the disclosure.

All the embodiments in this specification are described in a progressive way, and each embodiment focuses on the differences from other embodiments. The same and similar parts among the embodiments are referable to one another.

It should be also noted that herein, relational terms such as “first” and “second” are only used to distinguish one entity or operation from another entity or operation, and do not necessarily require or imply any such actual relationship or order between these entities or operations. The terms “comprise”, “include” or any other variations thereof, are intended to cover a non-exclusive inclusion, such that a process, method, article, or device which includes a list of elements does not include only those elements but also other elements not expressly listed or inherent to such process, method, article, or device. Without further limitation, an element defined by the statement “includes a . . . ” does not exclude the presence of another identical element in a process, method, article or device that includes the element.

The array substrate, the manufacturing method thereof and the display panel provided by the disclosure are described in detail above. Specific examples are applied herein to illustrate the principle and implementation of the disclosure. The above embodiments are only used to help understand the method of the disclosure and its core ideas. For those of ordinary skill in the art, according to the idea of the disclosure, there will be some changes in the specific implementation and application scope. To sum up, the contents of this specification should not be understood as a limitation of the disclosure.

1. An array substrate, comprising:
a substrate base;
a first transistor arranged on one side of the substrate base, the first transistor being located in an active area of the array substrate;
a flat layer covering the first transistor, the flat layer having a first through-hole;
a first electrode layer arranged in the first through-hole, the first electrode layer being connected with a drain of the first transistor and having a first groove;
a filling layer arranged in the first groove; and
a second electrode layer arranged on a side, away from the first transistor, of the filling layer, the second electrode layer being connected with the first electrode layer.

2. The array substrate according to claim 1, wherein a surface of a side, away from the first transistor, of the filling layer and a surface of a side, away from the first transistor, of the flat layer are on a same plane.

3. The array substrate according to claim 1, wherein the first transistor comprises a first active layer, a first gate insulating layer, a first gate, a first interlayer dielectric layer and a first source which are sequentially arranged on one side of the substrate base; and
the first source is connected with the first active layer through a first via hole penetrating through the first interlayer dielectric layer and the first gate insulating layer.

4. The array substrate according to claim 3, wherein the first transistor further comprises a first passivation layer covering the first source and the first interlayer dielectric layer, and a first drain arranged on the first passivation layer; and
the first drain is connected with the first active layer through a second via hole penetrating through the first passivation layer, the first interlayer dielectric layer and the first gate insulating layer.

5. The array substrate according to claim 3, wherein a second through-hole penetrates the first interlayer dielectric layer and the first gate insulating layer through-hole, and the second through-hole communicates with the first through-hole;
the first transistor further comprises a first drain arranged in the second through-hole, and the first drain is connected with the first active layer and has a second groove; and
the filling layer extends into the second groove.

6. The array substrate according to claim 1, wherein the first transistor comprises a second gate, a second interlayer dielectric layer, a second active layer, a second source and a second passivation layer which are sequentially arranged on one side of the substrate base; and
the second source partially covers the second active layer.

7. The array substrate according to claim 6, wherein the first transistor further comprises a second drain arranged on the second passivation layer; and
the second drain is connected with the second active layer through a third via hole penetrating through the second passivation layer.

8. The array substrate according to claim 6, wherein the second passivation layer has a third through-hole, and the third through-hole communicates with the first through-hole;
the first transistor further comprises a second drain arranged in the third through-hole, and the second drain is connected with the second active layer and has a third groove; and
the filling layer extends into the third groove.

9. The array substrate according to claim 1, further comprising a second transistor located in a GOA area, wherein the second transistor comprises a third active layer, a second gate insulating layer, a third gate, an insulating medium layer and a third source-drain electrode which are sequentially arranged on one side of the substrate base; and
a third source of the third source-drain electrode is connected with the third active layer through a fourth via hole penetrating through the insulating dielectric layer and the second gate insulating layer, a third drain of the third source-drain electrode is connected with the third active layer through a fifth via hole penetrating through the insulating dielectric layer and the second gate insulating layer, and the insulating dielectric layer comprises a third interlayer dielectric layer and a first gate insulating layer, or the insulating dielectric layer comprises a second interlayer dielectric layer.

10. The array substrate according to claim 1, wherein the first electrode layer and a drain of the first transistor are made of the same material, and both are a transparent conductive material; and
a material of an active layer of the first transistor is an oxide semiconductor.

11. The array substrate according to claim 1, further comprising a third passivation layer covering the second electrode layer and the flat layer, and a third electrode layer and a supporting structure located on a side, away from the second electrode layer, of the third passivation layer;
wherein the third electrode layer is located in the active area, and an overlapping area exists between an orthographic projection of the third electrode layer on the substrate base and an orthographic projection of the second electrode layer on the substrate base.

12. The array substrate according to claim 1, wherein both the first electrode layer and the second electrode layer are made of transparent conductive materials.

13. The array substrate according to claim 4, wherein when the first transistor is a top gate transistor, a drain of the first transistor is the first drain with a thickness of 50-600 nm, a source in the first transistor is the first source, and a gate in the first transistor is the first gate with a thickness of 300-700 nm.

14. The array substrate according to claim 4, wherein the first gate is made of metal.

15. The array substrate according to claim 4, wherein the material of the first passivation layer is at least one of silicon oxide and silicon nitride.

16. The array substrate according to claim 4, wherein a thickness of the first passivation layer is 50-300 nm.

17. The array substrate according to claim 9, wherein the second transistor is configured to provide a gate driving signal for the first transistor.

18. A display panel, comprising the array substrate according to claim 1.

19. A manufacturing method of an array substrate, comprising:
forming a first transistor on one side of a substrate base, the first transistor being located in an active area of the array substrate;
forming a flat layer covering the first transistor, the flat layer having a first through-hole;
forming a first electrode layer in the first through-hole, the first electrode layer being connected with a drain of the first transistor and having a first groove;
forming a filling layer in the first groove; and
forming a second electrode layer on a side, away from the first transistor, of the filling layer, the second electrode layer being connected with the first electrode layer.

20. The method according to claim 19, wherein a drain of the first transistor and the first electrode layer are simultaneously formed by a same patterning process.
